(19) United States
(12) Patent Application Publication
(10) Pub. No.: US 2026/0087219 A1
(43) Pub. Date: Mar. 26, 2026

(54) CARRY CHAIN REDUCTION AND REPLACEMENT FOR CIRCUIT DESIGNS

(71) Applicant: Xilinx, Inc., San Jose, CA (US)

(72) Inventors: Niyati Shah, Santa Clara, CA (US); Chun Zhang, San Jose, CA (US); Sandip Maity, Bangalore (IN); Fan Zhang, San Jose, CA (US)

(73) Assignee: Xilinx, Inc., San Jose, CA (US)

(21) Appl. No.: 18/898,044

(22) Filed: Sep. 26, 2024

(51) Int. Cl. G06F 30/337

(52) U.S. Cl. CPC G06F 30/337

(57) ABSTRACT

Carry chain reduction and/or replacement for circuit designs includes detecting, by computer hardware, a carry chain instance of a circuit design that is under-utilized. The carry chain instance has a first number of logic levels and includes one or more carry chain primitives dedicated for implementing carry chain logic. An updated carry chain instance is generated by the computer hardware. The updated carry chain instance has a second number of logic levels less than the first number of logic levels. The carry chain instance is replaced with the updated carry chain instance within the circuit design by the computer hardware.

### TECHNICAL FIELD

This disclosure relates to integrated circuits (IC) devices and, more particularly, to reducing and/or replacing carry chain circuitry for circuit designs for an IC device.

### BACKGROUND

Carry chain circuitry is an important aspect of modern circuit design. Carry chains are needed to build circuit structures such as adder circuitry. Adder circuitry, in turn, is a necessary building block of many other circuits used to perform operations such as addition, subtraction, multiplication, division, and/or many other operations.

Carry chains may be of particular significance for integrated circuit (IC) devices such as, for example, Application-Specific ICs (ASICs), programmable ICs, and/or Field-Programmable Gate Arrays (FPGAs). Often, adder circuit structures lie in timing critical paths of the circuit design.

In some IC devices, for example, some circuit structures used to implement carry chains have been hardened in an effort to implement efficient carry chain circuit architectures. These IC devices may include hard Intellectual Property (IP) cores dedicated, and sometimes reserved, for use in building carry chain circuitry. In some cases, the carry chain circuitry built using these hard IP cores tends to be large in size with many logic levels, but sparsely utilized. This tends to reduce the Quality of Result (QoR) achieved for the circuit design as implemented in a given, e.g., “target,” IC device. The reduction in QoR may manifest as a reduction in the maximum operating frequency of the circuit design as physically realized in the target IC device and/or an increase in the amount of circuit resources needed to physically realize the circuit design in the target IC device.

### SUMMARY

In one or more embodiments, a method includes detecting, by computer hardware, a carry chain instance of a circuit design that is under-utilized. The carry chain instance has a first number of logic levels and includes one or more carry chain primitives dedicated for implementing carry chain logic. The method includes generating, by the computer hardware, an updated carry chain instance having a second number of logic levels less than the first number of logic levels. The method includes replacing, by the computer hardware and within the circuit design, the carry chain instance with the updated carry chain instance.

In one or more embodiments, a system includes a memory capable of storing program instructions and a hardware processor capable of executing the program instructions to perform operations. The operations include detecting a carry chain instance of a circuit design that is under-utilized. The carry chain instance has a first number of logic levels and includes one or more carry chain primitives dedicated for implementing carry chain logic. The operations include generating an updated carry chain instance having a second number of logic levels less than the first number of logic levels. The operations include, replacing, within the circuit design, the carry chain instance with the updated carry chain instance.

In one or more embodiments, a computer program product includes a computer readable storage medium having program instructions embodied therewith. The program instructions are executable by computer hardware, e.g., a hardware processor, to cause the computer hardware to execute operations. The operations include detecting a carry chain instance of a circuit design that is under-utilized. The carry chain instance has a first number of logic levels and includes one or more carry chain primitives dedicated for implementing carry chain logic. The operations include generating an updated carry chain instance having a second number of logic levels less than the first number of logic levels. The operations include, replacing, within the circuit design, the carry chain instance with the updated carry chain instance.

This Summary section is provided merely to introduce certain concepts and not to identify any key or essential features of the claimed subject matter. Many other features and embodiments of the disclosed technology will be apparent from the accompanying drawings and from the following detailed description.

### BRIEF DESCRIPTION OF THE DRAWINGS

The accompanying drawings show one or more embodiments of the disclosed technology. The drawings, however, should not be construed to be limiting of the inventive arrangements to only the embodiments shown. Various aspects and advantages will become apparent upon review of the following detailed description and upon reference to the drawings.

FIG. 1 illustrates certain operative features of a system in accordance with one or more embodiments of the disclosed technology.

FIG. 2 illustrates a method of operation of the system of FIG. 1 in accordance with one or more embodiments of the disclosed technology.

FIG. 3 illustrates another method of operation of the system of FIG. 1 in accordance with one or more embodiments of the disclosed technology.

FIG. 4 illustrates a carry chain instance that is under-utilized in accordance with one or more embodiments of the disclosed technology.

FIG. 5 illustrates an updated carry chain instance corresponding to the carry chain instance of FIG. 4 in accordance with one or more embodiments of the disclosed technology.

FIG. 6 illustrates another carry chain instance that is under-utilized in accordance with one or more embodiments of the disclosed technology.

FIG. 7 illustrates an updated carry chain instance corresponding to the carry chain instance of FIG. 6 in accordance with one or more embodiments of the disclosed technology.

FIG. 8 illustrates another carry chain instance that is under-utilized in accordance with one or more embodiments of the disclosed technology.

FIG. 9 illustrates an updated carry chain instance corresponding to the carry chain instance of FIG. 8 in accordance with one or more embodiments of the disclosed technology.

FIG. 10 illustrates another carry chain instance that is under-utilized in accordance with one or more embodiments of the disclosed technology.

FIG. 11 illustrates an updated carry chain instance corresponding to the carry chain instance of FIG. 10 in accordance with one or more embodiments of the disclosed technology.

FIG. 12 illustrates another carry chain instance that is under-utilized in accordance with one or more embodiments of the disclosed technology.

FIG. 13 illustrates decomposition of decomposable logic in accordance with one or more embodiments of the disclosed technology.

FIG. 14 illustrates an updated carry chain instance corresponding to the carry chain instance of FIG. 12 in accordance with one or more embodiments of the disclosed technology.

FIG. 15 illustrates another carry chain instance that is under-utilized in accordance with one or more embodiments of the disclosed technology.

FIG. 16 illustrates an updated carry chain instance corresponding to the carry chain instance of FIG. 15 in accordance with one or more embodiments of the disclosed technology.

FIG. 17 illustrates an example implementation of a data processing system for use with the inventive arrangements described herein.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (IC) devices and, more particularly, to reducing and/or replacing carry chain circuitry for circuit designs for an IC device. In accordance with the inventive arrangements described within this disclosure, methods, systems, and computer program products are provided that are capable of reducing carry chain circuitry of a circuit design. The reduction in carry chain circuitry may be achieved by performing one or more optimization techniques to reduce a number of primitives of the carry chain circuitry and/or reduce a number of logic levels of the carry chain circuitry. In other examples, the reduction in carry chain circuitry may be achieved by replacing the carry chain circuitry with newly generated carry chain circuitry having fewer primitives and/or fewer logic levels.

By replacing carry chain circuitry with updated carry chain circuitry as described, whether by modification of existing carry chain circuitry or replacement thereof, the Quality of Result (QoR) of the circuit design may be improved. The QoR may be measured in terms of achieving a faster operating frequency for the circuit design including the updated carry chain circuitry as physically realized in a given or target IC device. The QoR may also be measured in terms of reducing the number or amount of circuit resources (e.g., circuit components) of the target IC device needed to implement the circuit design. This reduction often results in increased implementation options for the design tools when performing operations such as placement and routing.

In one or more embodiments, the reduction in carry chain circuitry may be achieved by replacing certain hard Intellectual Property (IP) cores that are reserved or dedicated for implementing carry chain circuitry with other circuit components such as lookup-tables (LUTs). As understood, LUTs are examples of combinatorial logic that do not require clocking. The hard IP cores are dedicated for use in implementing carry chains as the hard IP cores may not be used to implement any other aspects of the circuit design. By comparison, the LUTs used to replace the hard IP cores as part of the carry chain circuitry reduction performed may be general-purpose LUTs that are available for use in implementing non-carry chain circuitry of the circuit design. By replacing hard IP cores dedicated for carry chain logic implementation with general-purpose LUTs, the circuit design may be further optimized as discussed in greater detail hereinbelow.

Further aspects of the inventive arrangements are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

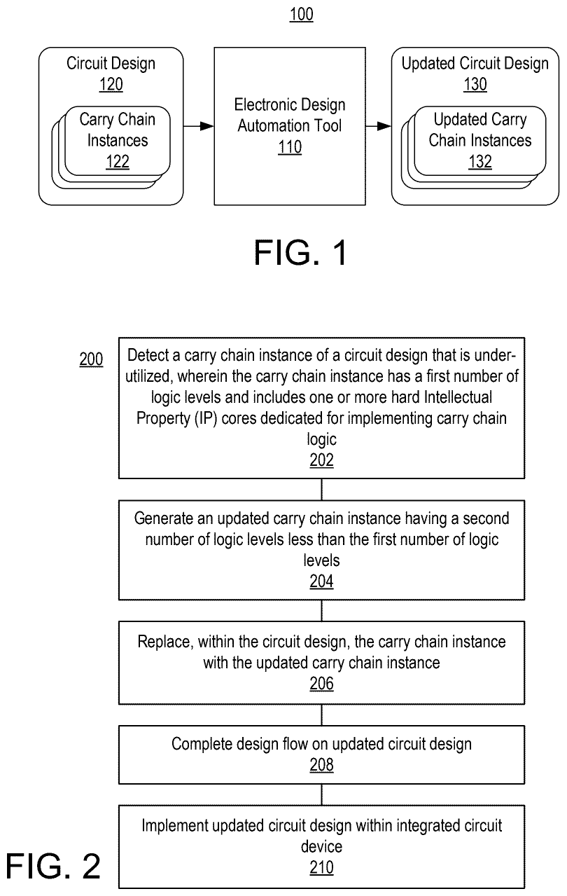

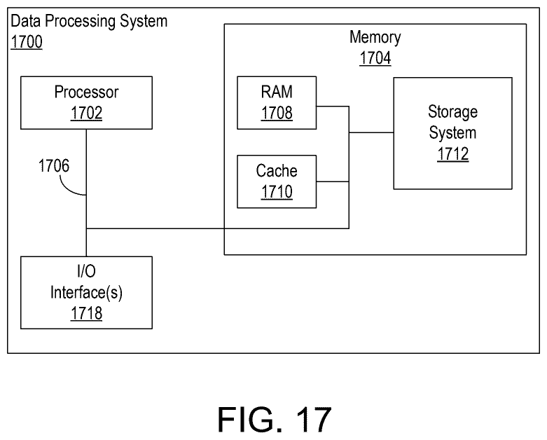

FIG. 1 illustrates certain operative features of a system 100 in accordance with one or more embodiments of the disclosed technology. System 100 may be implemented as a data processing system, e.g., a computer, executing suitable operational software in the form of program instructions. The program instructions, upon execution, cause the data processing system to perform one or more of the operations described within this disclosure. An example of a data processing system that may be used to implement system 100 is described in connection with FIG. 17.

In the example of FIG. 1, the program instructions may be embodied as an Electronic Design Automation (EDA) tool 110. As illustrated, EDA tool 110 is capable of receiving a circuit design 120 as input. Circuit design 120 may be a user-specified circuit design. Circuit design 120 may be stored in a memory device (not shown) of system 100. In the example, circuit design 120 has undergone synthesis and, as such, is synthesized for implementation in a particular IC device also referred to herein as a “target IC device.” As illustrated, circuit design 120 includes a plurality of carry chain instances 122.

EDA tool 110 is capable of operating on circuit design 120 to generate updated circuit design 130. Updated circuit design 130 is a modified and functionally equivalent version of circuit design 120. As illustrated, within updated circuit design 130, carry chain instances 122 have been replaced with updated carry chain instances 132. Updated carry chain instances 132, e.g., each such instance, includes fewer logic levels and/or fewer primitives than the particular carry chain instance 122 the updated carry chain instance 132 replaces. As discussed, updated carry chain instances 132 may be generated by modifying (e.g., applying an optimization technique) to one or more carry chain instances 122, by generating a completely new carry chain instance as the updated carry chain instance to replace the existing or prior carry chain instance, or by way of a combination of both across carry chain instances of circuit design 120. It should be appreciated that in each case of replacing or updating a given carry chain instance with a corresponding updated carry chain instance, the circuit design pre-update and the circuit design post update are functionally equivalent.

FIG. 2 illustrates a method 200 of operation of system 100 of FIG. 1 in accordance with one or more embodiments of the disclosed technology. Method 200 may begin in a state where a circuit design has undergone a portion of a design flow such that the circuit design, e.g., circuit design 120, is synthesized.

In block 202, system 100 is capable of detecting a carry chain instance of circuit design 120. The carry chain instance that is detected is one that is under-utilized. Further, the carry chain instance that is detected has a first number of logic levels and includes one or more hard IP cores dedicated for implementing carry chain logic.

As generally understood, the term “Intellectual Property core” or “IP core” means a pre-designed and reusable unit of logic design, a cell, or a portion of chip layout design in the field of electronic circuit design. A hard IP core refers to a circuit structure of an IC device that is manufactured as part of the IC device. Unlike programmable circuitry such as a configurable logic block or a lookup-table (LUT), the functionality of hardwired circuitry such as a hard IP core may not be programmed after the manufacture of the IC device by loading configuration data therein. A hard IP core is generally considered to have dedicated circuit blocks and interconnects, for example, that are functional without first loading configuration data into the IC device. In some instances, a hard IP core may have one or more operational modes that can be set or selected according to register settings or values stored in one or more memory elements within the IC device. Despite this ability, a hard IP core is not considered programmable circuitry as the hard IP core is operable and has a particular function when manufactured as part of the IC.

In one or more embodiments, system 100 detects that the carry chain instance is under-utilized using one or more heuristics. An example of a heuristic indicating an under-utilized carry chain includes detecting that at least one programmable LUT (e.g., a LUTCY as described in greater detail below) of the carry chain that has “k” inputs is using “c” inputs, where c is less than k. In one or more embodiments, constants such as an input of the programmable LUT tied to a logic high or a logic low are not included in the count of c.

In other examples, the heuristic indicating an under-utilized carry chain may include detecting that a ratio of a number of input pins of the one or more carry chain primitives of the carry chain instance connected to an active signal to a total number of input pins of the one or more carry chain primitives exceeds a predetermined threshold. Another example of a heuristic can include detecting that a number of input signals cut by an input cut for the carry chain instance is less than or equal to an input signal threshold and a number of output signals cut by an output cut of the carry chain instance is less than or equal to an output signal threshold.

In one or more embodiments, a carry chain instance may be selected for processing as one that includes a critical path. For example, the system may select a carry chain instance on a signal path of the circuit design that is not meeting a predetermined timing requirement. The system may select a carry chain instance on a signal path that is considered to be slow or slower than other signal paths or slowest regardless of whether the path meets a predetermined timing requirement.

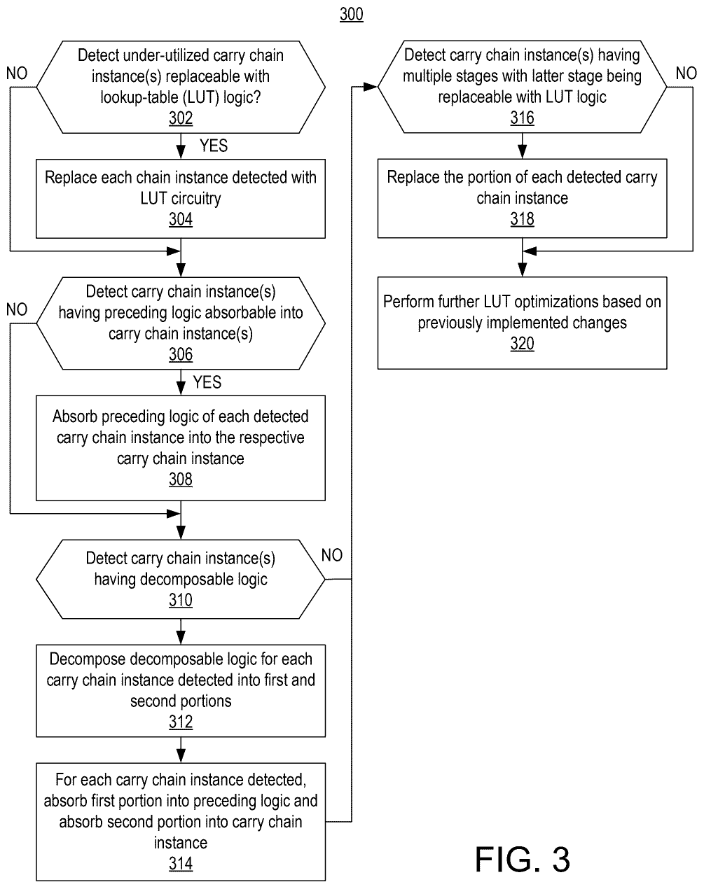

In block 204, system 100 is capable of generating an updated carry chain instance having a second number of logic levels that is less than the first number of logic levels of the carry chain instance. The updated carry chain instance is functionally equivalent to the detected carry chain instance being replaced. As discussed, the updated carry chain instance may be generated by operating on the carry chain instance to reduce the number of logic levels and/or primitives used, by generating a new carry chain instance as the updated carry chain instance, and/or performing one or more other operations to be described herein in greater detail below in connection with FIG. 3.

In block 206, system 100 is capable of replacing the carry chain instance within circuit design 120 with the updated carry chain instance. Circuit design 120, as updated with the updated carry chain instance, results updated circuit design 130.

In block 208, system 100 is capable of completing the design flow. For example, further operations may be performed depending on the particular type of IC device in which updated circuit design 130 is to be implemented. As an illustrative and nonlimiting example, system 100 may perform further operations such as placement and routing on updated circuit design 130. In block 210, system 100 is capable of implementing updated circuit design 130 within the target IC device. For example, any configuration data generated specifying the placed and routed version of updated circuit design 130 may be loaded into the IC device thereby physically realizing updated circuit design 130 in the IC device. As discussed, as implemented in the target IC device, updated circuit design 130 will have improved QoR as compared to implementing circuit design 120 within the IC device.

FIG. 3 illustrates a method 300 of operation of system 100 of FIG. 1 in accordance with one or more embodiments of the disclosed technology. FIG. 3 illustrates an example method of operation that is capable of reducing and/or replacing carry chain instances of a circuit design. Execution of method 300 on a circuit design such as circuit design 120 is capable of reducing the number of logic levels of one or more or all of the carry chain instances of the circuit design and/or reducing resource usage of the circuit design compared to the updated version of the circuit design as implemented within the target IC device.

In the example of FIG. 3, different techniques for updating or optimizing carry chain circuitry are described. In one or more embodiments, each of these techniques may be performed on the circuit design undergoing processing. It should be appreciated that while each of these techniques is described as being performed in the example of FIG. 3, any one (e.g., or more) of the techniques described in connection with FIG. 3 may be executed on a circuit design individually or with one or more other ones of the techniques as part of block 206 of FIG. 2. In one or more embodiments, method 300 may be performed to implement blocks 206 and 208. Further, to the extent that no carry chain instance meets the requirements (e.g., heuristics) for a given technique, such technique may not be performed on the circuit design (e.g., the technique may be skipped or omitted from method 300).

Method 300 may begin in a state where circuit design 120 has been synthesized. Accordingly, in block 302, system 100 is capable of detecting one or more under-utilized carry chain instances that are replaceable with LUT logic. In response to detecting one or more under-utilized carry chain instances that are replaceable with LUT logic, method 300 continues to block 304. In response to detecting no under-utilized carry chain instances that are replaceable with LUT logic, method 300 continues to block 306. In block 304, system 100 is capable of replacing each detected under-utilized carry chain instance with LUT logic. In one or more embodiments, system 100 is capable of replacing one or more or each carry chain instance detected in block 302 with a single LUT primitive and/or a plurality of LUT primitives. The LUT primitive(s) used to replace the carry chain logic may be general-purpose LUT primitive(s).

With reference to blocks 302 and 304, system 100 is capable of detecting that a carry chain instance is under-utilized and, as such, replaceable in several different circumstances described in greater detail hereinbelow. For purposes of illustrating the various heuristics described herein in connection with carry chain circuitry in general, example carry chain circuitry and primitives used to create the carry chain circuitry are described.

For example, carry chain circuitry described herein can include one more LUTCY primitives and one or more Lookahead8 primitives. The LUTCY primitive is a type of LUT that may be used to implement a 1-bit adder or up to a 2-bit comparator. Unused LUTCY primitives may be used to implement non-carry chain logic of a circuit design. The Lookahead8 primitive is a hard IP core that is reserved exclusively for use in implementing carry chain circuitry in the target IC device. As such, the Lookahead8 primitives are not available to implement other portions of a circuit design. For example, a Lookahead8 primitive is not permitted to be used to implement any circuitry or logic of a circuit design other than carry chain logic or circuitry, whereas a LUTCY primitive may. In general, the Lookahead8 primitives are used to propagate carry values forward so as to avoid the necessity of waiting for L-1 logic levels of the carry chain instance to compute the carry value for the Lth level. That is, the Lookahead8 primitives are used to speed up the carry propagation.

Due to the heterogeneous nature of carry chains, carry chain synthesis is usually performed as a separate or independent stage of an implementation flow (e.g., separately from synthesis of other portions of the circuit design). The carry chain synthesis process treats carry chain logic separately and, as such, does not attempt to fuse preceding logic into the carry chain logic. Under-utilization of the carry chain circuitry is often exacerbated as the carry chain circuitry usually implements only a 1-bit sum per stage. This situation, taken in combination with other circuit design optimization techniques such as constant propagation, can lead to carry chain circuitry that is sparsely (e.g., under) utilized where only a relatively small number of input pins of the total input pin capacity of the carry chain instance are driven by active signals.

In one or more embodiments, a carry chain instance is considered under-utilized and replaceable with LUT logic based on the number of input signals provided to the carry chain instance and/or the number of signals output from the carry chain instance. With respect to input signals, for a carry chain instance to be replaceable, the number of input signals M cut by an input cut of the carry chain instance must be less than or equal to a predetermined threshold number of input signals Tᵢ also referred to as an input signal threshold such that M≤Tᵢ. In one or more embodiments, Tᵢ may be set equal to the number of inputs of an available general-purpose LUT primitive of the target IC device. The particular LUT primitive used may be a LUT primitive with the largest number of inputs or a LUT primitive having a total of k inputs. For purposes of illustration, Tᵢ=6 or k, for example.

With respect to output signals of the carry chain instance, the number of output signals N cut by an output cut of the carry chain instance must be less than or equal to a predetermined threshold number of output signals Tₒ also referred to as an output signal threshold such that N≤Tₒ. In one or more embodiments, Tₒ is set equal to 1. In this example, Tₒ is set to the number of output signals that the same general-purpose LUT primitive used for setting Tᵢ may be used. By applying the heuristics Tᵢ (e.g., six) and Tₒ (e.g., one) to the input signals and output signals, respectively, of the carry chain instance, system 100 ensures that the entire carry chain instance may be replaced by a single general-purpose LUT primitive.

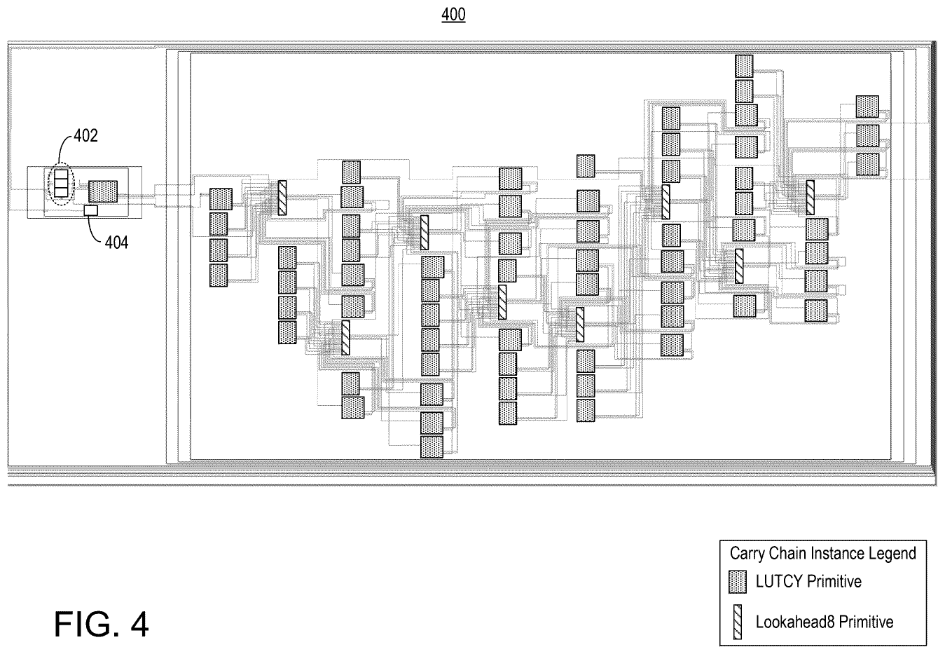

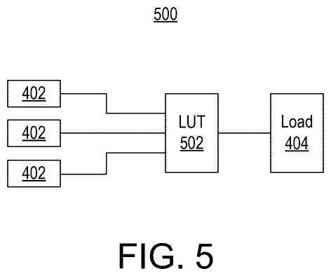

FIGS. 4 and 5 illustrate an example implementation of blocks 302 and 304 using the heuristics M≤Tᵢ and N≤Tₒ.

FIG. 4 illustrates an example of a carry chain instance 400 that is under-utilized as may be included in circuit design 120. In the example, carry chain instance 400 includes 72 primitives shown with shading illustrated in the legend. Carry chain instance 400 includes 64 LUTCY primitives and 8 Lookahead8 primitives. In the example, carry chain instance 400 has three inputs, e.g., flip-flops (FFs), 402 and drives one load 404. As illustrated, there are three input signals fed into the carry chain logic instance such that the input cut is three. These signals propagate through the many levels of carry chain instance 400. Carry chain instance 400 outputs a single signal that drives load 404 such that the output cut is one. As such, carry chain instance 400 is illustrative of a replaceable carry chain instance that meets the conditions M≤Tᵢ and N≤Tₒ.

FIG. 5 illustrates updated carry chain instance 500. In the example of FIG. 5, system 100 has generated updated carry chain instance 500. System 100 is capable of replacing the entirety of carry chain instance 400 as illustrated in FIG. 4 with updated carry chain instance 500. That is, carry chain instance 400 is replaced in whole by updated carry chain instance 500. Updated carry chain instance 500 includes a single, general-purpose LUT primitive 502. As shown, general-purpose LUT primitive 502 receives the three inputs 402 and generates a single output that drives load 404.

In the example of FIGS. 4 and 5, the updated carry chain instance includes fewer logic levels or fewer primitives, or both, than the carry chain logic being replaced. In one or more embodiments, system 100 may compare the updated carry chain instance with the carry chain instance being replaced. In response to the updated carry chain instance not having fewer logic levels, not having fewer primitives, or not having both fewer logic levels and fewer primitives, system 100 may revert the circuit design back to the original carry chain instance (e.g., carry chain instance 400 in this example).

In one or more embodiments, a carry chain in instance is considered replaceable based on the number of input pins of the carry chain instance that are used compared to the number of input pins of the carry chain instance. As discussed, within this disclosure, an input pin of the carry chain instance that is used is one that is tied, or connected, to an active signal. An active signal is one that may change state during operation, e.g., a signal that is not a constant. An input pin of the carry chain instance that is not used is one that is tied to a constant such as a logic high (e.g., a power rail such as VDD) or a logic low (a power rail such as ground or VSS).

In an example implementation, the system compares a ratio of the number of input pins of the carry chain instance that are used to the total number of input pins of the carry chain instance (e.g., inclusive of pins that are not used) to a threshold. In response to the ratio, or fraction, exceeding the threshold, system 100 detects the carry chain instance as being one that is replaceable. In such cases, the circuitry used to replace the carry chain instance may include more than one LUT primitive and, as such, may be used in cases where the number of input signals M to the carry chain instance is not less than or equal to the threshold Tᵢ (e.g., the expression M≤Tᵢ is not true where Tᵢ=k) and/or the number of output signals N is not less than or equal to the threshold Tₒ (e.g., the expression N≤Tₒ is not true where Tₒ=1).

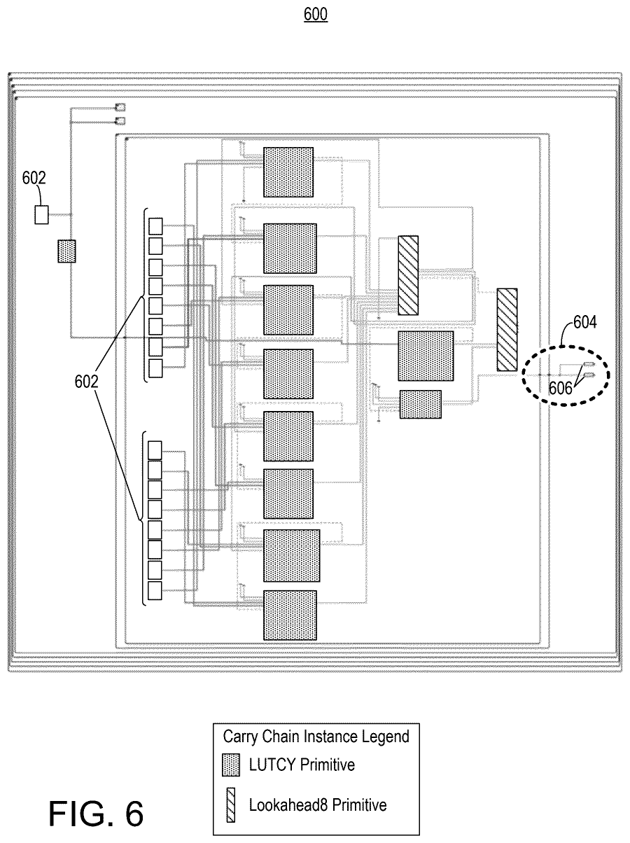

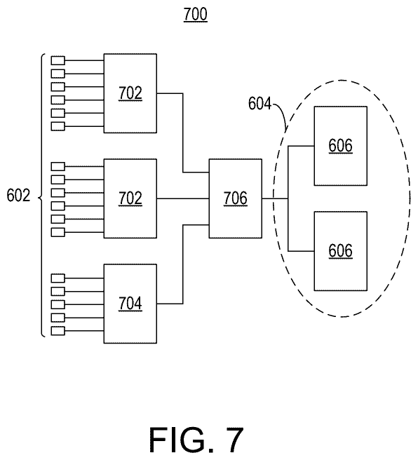

FIGS. 6 and 7 illustrate an example implementation of blocks 302 and 304 using the heuristics corresponding to the ratio, or fraction, of the number of input pins of the carry chain instance that are used to the total number of input pins of the carry chain instance.

FIG. 6 illustrates an example of a carry chain instance 600 that is under-utilized as may be included in circuit design 120. In the example, carry chain instance 600 includes a plurality of LUTCYs and a plurality of Lookahead8 primitives. Further carry chain instance 600 includes 17 inputs 602 and has a single output 604 that drives two loads 606. In the example of FIG. 6, the ratio of the number of input pins of carry chain instance 600 that are used (e.g., the input cut) to the total number of input pins of carry chain instance 600 exceeds the predetermined threshold. As such, system 100 has identified carry chain instance 600 as one that is replaceable despite the expression M≤Tᵢ, where Tᵢ=k, being untrue. In one or more other embodiments, the system is capable of using, as the heuristic, a ratio of the number of input pins of carry chain instance 600 that are used to the total number of input pins of carry chain instance 600 that considers all of the carry chain primitives of the carry chain instance beyond the input cut or output cut.

FIG. 7 illustrates updated carry chain instance 700. In the example of FIG. 7, system 100 has replaced the entirety of carry chain instance 600 as illustrated in FIG. 6 with updated carry chain instance 700. Updated carry chain instance 700 includes two general-purpose LUT primitives 702 each using six inputs, one general-purpose LUT primitive 704 using five inputs and one general-purpose LUT primitive 706 using three inputs. LUT primitive 706 provides the single output 604 driving the two loads 606.

In the example of FIGS. 6 and 7, the updated carry chain instance includes fewer logic levels or fewer primitives, or both, than the carry chain logic being replaced. As discussed in connection with FIGS. 4 and 5, system 100 is capable of performing a check to ensure that the updated carry chain instance is an improvement over the original carry chain instance. If not, system 100 is capable of reverting the circuit design to the original carry chain instance (e.g., carry chain instance 600 in this example).

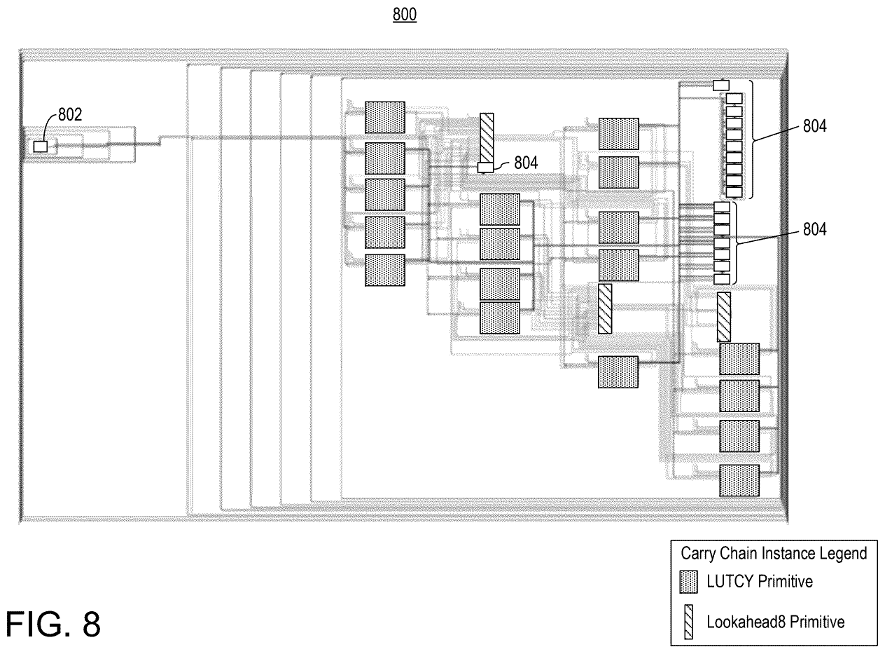

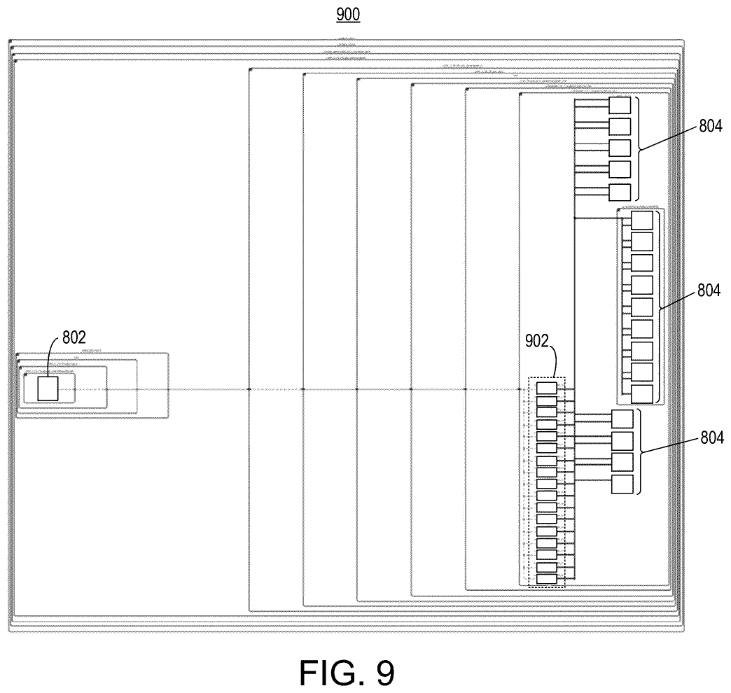

FIGS. 8 and 9 illustrate a further example implementation of blocks 302 and 304 using the heuristic corresponding to the ratio, or fraction, of the number of input pins of the carry chain instance that are used to the total number of input pins of the carry chain instance.

FIG. 8 illustrates an example of a carry chain instance 800 that is under-utilized as may be included in circuit design 120. In the example, carry chain instance 800 includes one driver 802 and is driving 17 unique output nets with 18 loads 804. Carry chain instance 800 includes a total of 3 Lookahead8 primitives and 18 LUTCY primitives.

FIG. 9 illustrates updated carry chain instance 900. In the example of FIG. 9, system 100 has replaced the entirety of carry chain instance 800 as illustrated in FIG. 8 with updated carry chain instance 900. Updated carry chain instance 900 includes 17 general-purpose LUT primitives 902 each using one input and each driving one the 17 output nets.

In the example of FIGS. 8 and 9, the updated carry chain instance includes fewer logic levels or fewer primitives, or both, than the carry chain logic being replaced. As discussed in connection with FIGS. 4 and 5, system 100 is capable of performing a check to ensure that the updated carry chain instance is an improvement over the original carry chain instance. If not, system 100 is capable of reverting the circuit design to the original carry chain instance (e.g., carry chain instance 800).

Continuing with FIG. 3, in block 306, system 100 is capable of detecting one or more carry chain instances having logic that is absorbable into the carry chain instance(s). In general, absorbable logic is logic surrounding a carry chain instance whether preceding the carry chain instance or following the carry chain instance. In one or more embodiments, the logic that is absorbable may be logic that precedes the carry chain instance. Logic that precedes the carry chain instance can include circuitry that directly drives the carry chain instance. For example, an input cone of the carry chain logic may include a circuit component that generates a signal that is provided to an input of the carry chain instance. Such a circuit component may be absorbed by the carry chain instance.

In one or more embodiments, the logic that is absorbable may be logic that immediately follows the carry chain instance. Logic that immediately follows the carry chain instance includes logic that is directly driven by a carry chain instance. For example, an input signal of the logic immediately following the carry chain instance will have been generated by an output from a circuit component of the carry chain instance.

In response to detecting one or more carry chain instances having logic that is absorbable into the carry chain instance, method 300 continues to block 308. In response to detecting that no carry chain instance has logic that is absorbable into the carry chain instance, method 300 continues to block 310. In block 308, system 100 is capable of absorbing the logic of each detected carry chain instance into the respective carry chain instance.

An example heuristic for detecting logic that is absorbable is comparing a number of available (e.g., unused) input pins of a carry chain primitive that is directly connected to the circuit component being considered for absorption is large enough to absorb or accommodate the input signals of the circuit component to be absorbed.

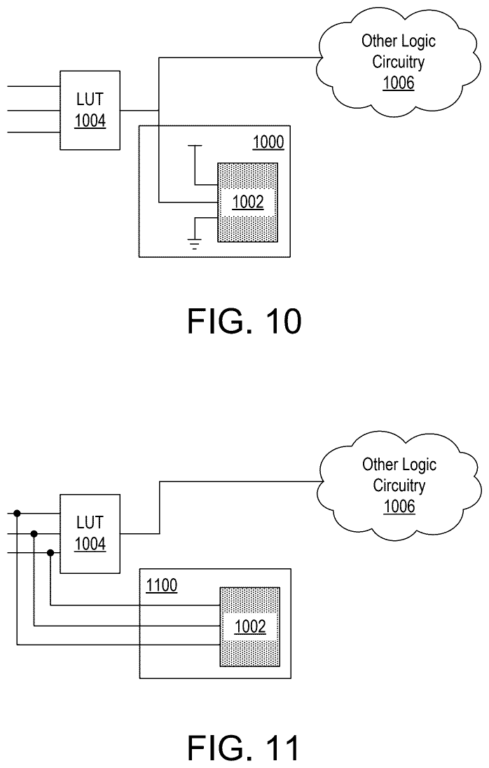

FIGS. 10 and 11 illustrate an example implementation of blocks 306 and 308 using a heuristic in which system 100 detects that the number of available input pins of a carry chain primitive that is directly connected to the circuit component to be absorbed is large enough to absorb or accommodate the input signals of the circuit component to be absorbed.

FIG. 10 illustrates an example of a carry chain instance 1000 that is under-utilized as may be included in circuit design 120. In the example, LUTCY primitive 1002 of carry chain instance 1000 is under-utilized with one pin tied to logic high and another pin tied to logic low. LUT primitive 1004 is a general-purpose LUT that has multi-fanout in that LUT primitive 1004 drives both other logic circuitry 1006, which may include one or more loads, and LUTCY primitive 1002.

FIG. 11 illustrates updated carry chain instance 1100. In the example of FIG. 11, system 100 has absorbed LUT 1004 into LUTCY primitive 1002 and performed implicit replication. As shown, the previously unused input pins of LUTCY primitive 1002 are now occupied as LUTCY primitive 1002 receives as input the same signals provided to LUT primitive 1004. This reduces the number of logic levels leading into carry chain instance 1000 by one as illustrated in FIG. 11, while also retaining LUT primitive 1004 to drive other logic circuitry 1006.

In the example of FIGS. 10 and 11, system 100 is capable of detecting a selected circuit component, e.g., LUT primitive 1004, that drives carry chain instance 1000 and one or more other loads shown as other logic circuitry 1006. System 100 is capable of creating a replicated version of the selected circuit component (e.g., a replicated version of LUT primitive 1004) to drive the one or more other loads. System 100 further is capable of absorbing the selected circuit component into the carry chain instance resulting in the updated carry chain instance. As illustrated, LUT primitive 1004 is absorbed into LUTCY primitive 1002, leaving the replicated version of LUT primitive 1004.

In the example of FIGS. 10 and 11, the resulting circuitry, inclusive of the updated carry chain instance, includes fewer logic levels than the previous circuitry. Similar to the discussion in connection with FIGS. 4 and 5, system 100 is capable of performing a check to ensure that the resulting circuitry is an improvement over the prior circuitry in terms of reduced logic levels, reduced number of primitives used, or both. If not, system 100 is capable of reverting the circuit design to the original implementation (e.g., reverting to the example of FIG. 10).

Continuing with FIG. 3, in block 310, system 100 is capable of detecting one or more carry chain instances having logic that is decomposable. More particularly, system 100 is capable of detecting carry chain instances that are preceded by logic that may be decomposed into logic that then may be absorbed by the respective carry chain instance(s) and logic that precedes the decomposable logic. The decomposable logic will be in the input cone to the respective carry chain instance. In response to detecting one or more carry chain instances having logic that is decomposable, method 300 continues to block 312. In response to detecting that no carry chain instance has logic that is decomposable, method 300 continues to block 316.

In block 312, system 100 is capable of decomposing the decomposable logic of each carry chain instance detected in block 310 into a first portion and a second portion. In one or more embodiments, the first portion may be of a size that fits into a general-purpose LUT primitive on the target IC device. Similarly, the second portion may be a size that fits into a general-purpose LUT primitive on the device. For purposes of illustration, system 100 is capable of performing Shannon Decomposition, Ashenhurst-Curtis Decomposition, or another decomposition technique on the decomposable logic to generate the constituent portions described. In block 314, for each carry chain instance detected in block 310, system 100 absorbs the first portion into the preceding logic and absorbs the second portion into the respective carry chain.

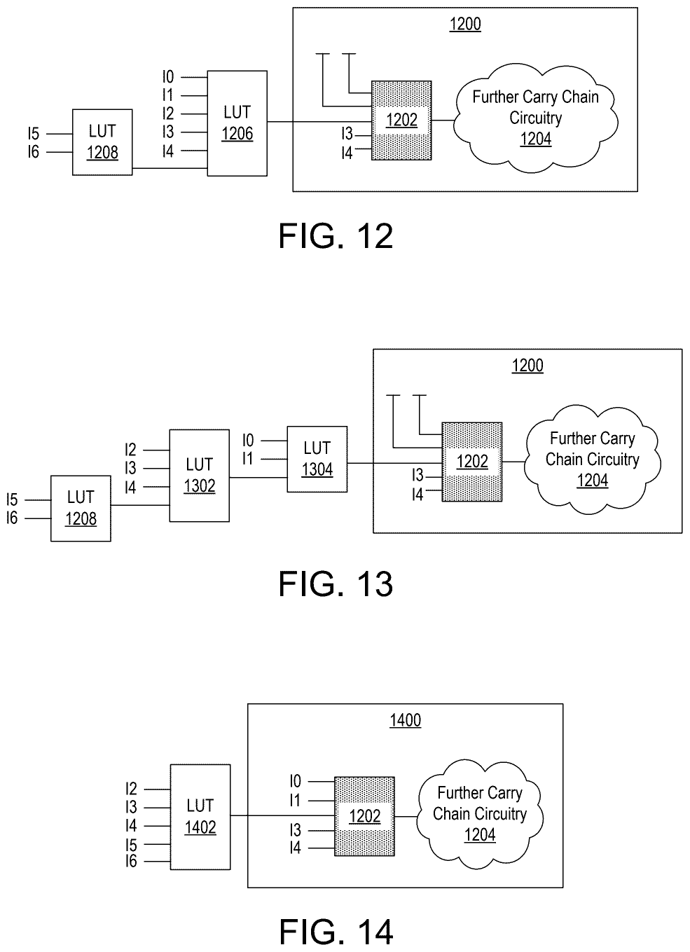

FIGS. 12, 13, and 14 illustrate an example implementation of blocks 310, 312, and 314. FIG. 12 illustrates an example of a carry chain instance 1200 that is under-utilized as may be included in circuit design 120. In the example, LUTCY primitive 1202 of carry chain instance 1200 is under-utilized with two pins tied to logic high. As illustrated, LUTCY primitive 1202 drives further carry chain circuitry 1204 (e.g., one or more additional LUTCY primitives and/or one or more Lookahead8 primitives). LUTCY primitive 1202 receives an output from LUT primitive 1206, which is a general-purpose LUT primitive having 6 inputs. Further, LUT primitive 1206 receives an input from LUT primitive 1208. LUT primitive 1208 has two inputs. In the example, LUT primitive 1206 is decomposable logic and LUT primitive 1208 is circuitry or logic that precedes, e.g., drives, the decomposable logic.

FIG. 13 illustrates decomposition of the decomposable logic. As illustrated system 100 has decomposed LUT primitive 1206 into logical LUT 1302 and logical LUT 1304. Each of logical LUTs 1302, 1304 may be implemented as a general-purpose LUT primitive. Further, logical LUT 1302 uses four inputs while logical LUT 1304 uses three inputs. In the example of FIG. 13, logical LUT 1302 represents the first portion from the decomposition and logical LUT 1304 represents the second portion from the decomposition.

FIG. 14 illustrates updated carry chain instance 1400. In the example of FIG. 14, system 100 has absorbed the first portion (e.g., logical LUT 1302) into LUT primitive 1402, which effectively replaces both LUT primitive 1208 (e.g., a LUT primitive with two inputs used) and logical LUT 1302 requiring four inputs with LUT primitive 1402 having all six inputs used. Further, system 100 has absorbed logical LUT 1304 requiring three inputs into LUTCY primitive 1202. As may be observed through comparison of FIG. 12 and FIG. 14, the number of logic levels and the number of primitives has been reduced.

In the example of FIGS. 12, 13, and 14, the system is capable of detecting the number of free or unused pins on LUTCY primitive 1202. The system further decomposes the preceding logic, e.g., LUT primitive 1206 into a logical LUT 1304 that uses some number of inputs that is less than or equal to the number of unused inputs on LUTCY primitive 1202, which includes the input pin coupled to the output of logical LUT 1304. Similarly, the system is capable of detecting the number of free or unused pins on LUTCY primitive 1202. The system performs a similar process with respect to combining, or merging, LUT primitive 1208 with logical LUT 1302 resulting in LUT primitive 1402 (e.g., where the total number of inputs required to combine LUT primitive 1208 with logical LUT 1302 does not exceed the capacity of the LUT primitive 1402).

In the example of FIGS. 12, 13, and 14, the resulting circuitry, inclusive of the updated carry chain instance, includes fewer logic levels and fewer primitives than the previous circuitry. Similar to the discussion in connection with FIGS. 4 and 5, system 100 is capable of performing a check to ensure that the resulting circuitry is an improvement over the prior circuitry in terms of reduced logic levels, reduced number of primitives used, or both. If not, system 100 is capable of reverting the circuit design to the original implementation (e.g., reverting to the example of FIG. 12).

Continuing with FIG. 3, in block 316, system 100 is capable of detecting carry chain instance(s) having a portion, e.g., a latter or last stage, of the carry chain instance that is replaceable with LUT logic. In response to detecting one or more carry chain instances having a portion that is replaceable, method 300 continues to block 318. In response to detecting that no carry chain instance has a portion that is replaceable, method 300 continues to block 320. In block 318, system 100 is capable of replacing the portion of the carry chain instance of each respective carry chain instance detected in block 316 with LUT logic. That is, the carry chain logic is replaced, at least in part, to generate the updated carry chain logic.

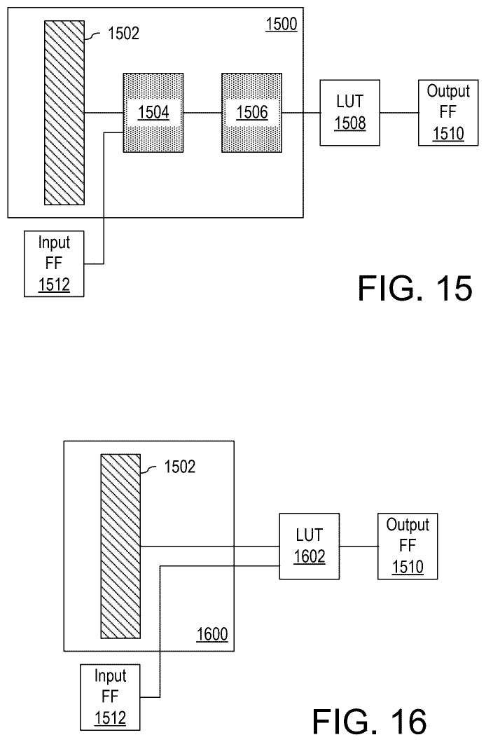

FIGS. 15 and 16 illustrate an example implementation of blocks 316 and 318.

FIG. 15 illustrates an example of a carry chain instance 1500 that includes a latter portion that is under-utilized as may be included in circuit design 120. In the example, carry chain instance 1500 includes a Lookahead8 primitive 1502 followed by two LUTCY primitives 1504, 1506. A first input of LUTCY primitive 1504 is received from Lookahead8 1502 and a second input of LUTCY primitive 1504 is received from input FF 1512. LUTCY primitive 1506 drives a LUT primitive 1508, which may be a general-purposes LUT primitive using one input. LUT primitive 1508 drives an output FF 1510. In the example of FIG. 15, both LUTCY primitives 1504, 1506 are under-utilized.

In the example of FIG. 15, the system is capable of detecting a carry chain in which a last stage of the carry chain does not have multiple output nets (e.g., has a single output net). Further, the system detects that the last stage of the carry chain is followed by one or more levels of fully absorbable logic (referred to as L1s for purposes of description below). An example of the fully absorbable logic detected by the system is one or more LUT primitives. In other words, the loads of the last stage of the carry chain must have one or more absorbable LUT primitives. If, for example, all of the loads of the last stage of the carry chain are FFs, the system would not proceed with processing the carry chain instance.

FIG. 16 illustrates updated carry chain instance 1600. In the example of FIG. 16, the system has replaced both of LUTCY primitives 1504, 1506 with a general-purpose LUT primitive shown as LUT primitive 1602. Further, the system has absorbed LUT primitive 1508 into LUT 1602.

For purposes of illustration, the input cut of the last stage of the carry chain may be denoted as “y.” In the example, for L1s having an input cut of “x” such that x+y≤6, the system creates a LUT called L2 that is logically equivalent to the last stage of the carry chain (e.g., LUTCY primitives 1504, 1506) such that the last stage of the carry chain may then be combined with L1 to create a single LUT primitive L3. In this manner, the system guarantees a reduction of one logic level for all such L1s. For L1s where the input cut is “x” such that x+y>6, the system leaves the original carry chain unchanged.

In the example of FIGS. 15 and 16, the resulting circuitry, inclusive of the updated carry chain instance, includes fewer logic levels than the previous circuitry.

Similar to the discussion in connection with FIGS. 4 and 5, system 100 is capable of performing a check to ensure that the resulting circuitry is an improvement over the prior circuitry in terms of reduced logic levels, reduced number of primitives used, or both. If not, system 100 is capable of reverting the circuit design to the original implementation (e.g., reverting to the example of FIG. 15).

In block 320, system 100 is capable of performing further LUT optimizations on the circuit design based on the previously implemented changes. For example, having converted one or more carry chain logic instances, or portions thereof, from using dedicated carry chain primitives including hard IP core(s) such as the Lookahead8 primitive, a variety of further LUT optimizations may be performed in which the number of logic levels and/or LUT primitives may be further reduced as any restriction(s) to such operations that are applicable to dedicated carry chain circuitry are not applicable to the general-purpose LUT primitives used to replace such circuitry.

For example, the updated carry chain instance of FIG. 9 may be further optimized so that the entire carry chain structure may be removed. That is, each of the 17 LUT primitives may be removed. In another example, both of the LUT primitives 708 of FIG. 7 may be further optimized by absorbing such circuit components into LUT primitive 706. In one or more other embodiments, a carry chain instance that includes one or more general-purposes LUT primitives disposed between a first under-utilized LUTCY primitive and a second under-utilized LUTCY primitive may be processed by decomposing the general-purposes LUT primitive into a first portion and a second portion, absorbing the first portion into the first under-utilized LUTCY primitive, and absorbing the second portion into the second under-utilized LUTCY primitive.

As discussed, in cases where the operations described in connection with FIG. 3 are performed as part of method 200 of FIG. 2, the process may continue by performing additional operations such as performing any additional circuit design implementation phases that may be required to physically realize the circuit design within the target IC device. For example, system 100 is capable of performing placement, routing, and/or configuration data generation. Further, system 100, or another system coupled to the target IC device, may load the configuration data into the target IC device. It should be appreciated that loading the configuration data into the target IC device physically realizes updated circuit design 130 having updated carry chain instances 132 therein within the target IC device. As discussed, the updated circuit design 130 will utilize fewer circuit resources of the target IC device and have a higher maximum operating frequency owing, at least in part, to the modifications described herein in connection with the carry chain instance(s).

FIG. 17 illustrates an example implementation of a data processing system 1700. As defined herein, the term “data processing system” means one or more hardware systems configured to process data, each hardware system including at least one processor and memory, wherein the processor is programmed with computer-readable program instructions that, upon execution, initiate operations. Data processing system 1700 can include a processor 1702, a memory 1704, and a bus 1706 that couples various system components including memory 1704 to processor 1702.

Processor 1702 may be implemented as one or more processors. In an example, processor 1702 is implemented as a hardware processor such as a central processing unit (CPU). Processor 1702 may be implemented as one or more circuits capable of carrying out instructions contained in program code. The circuit(s) may be an IC or embedded in an IC. Processor 1702 may be implemented using a complex instruction set computer architecture (CISC), a reduced instruction set computer architecture (RISC), a vector processing architecture, or other known architectures. Example processors include, but are not limited to, processors having an x86 type of architecture (IA-32, IA-64, etc.), Power Architecture, ARM processors, and the like.

Bus 1706 represents one or more of any of a variety of communication bus structures. By way of example, and not limitation, bus 1706 may be implemented as a Peripheral Component Interconnect Express (PCIe) bus. Data processing system 1700 typically includes a variety of computer system readable media. Such media may include computer-readable volatile and non-volatile media and computer-readable removable and non-removable media.

Memory 1704 can include computer-readable media in the form of volatile memory, such as random-access memory (RAM) 1708 and/or cache memory 1710. Data processing system 1700 also can include other removable/non-removable, volatile/non-volatile computer storage media. By way of example, storage system 1712 can be provided for reading from and writing to a non-removable, non-volatile magnetic and/or solid-state media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1706 by one or more data media interfaces. Memory 1704 is an example of at least one computer program product.

Memory 1704 is capable of storing computer-readable program instructions that are executable by processor 1702. For example, the computer-readable program instructions can include an operating system, one or more application programs, other program code, and program data. Processor 1702, in executing the computer-readable program instructions, is capable of performing the various operations described herein that are attributable to a computer. In one or more examples, the compute-readable program instructions may implement EDA tool 110.

It should be appreciated that data items used, generated, and/or operated upon by data processing system 1700 are functional data structures that impart functionality when employed by data processing system 1700. As defined within this disclosure, the term “data structure” means a physical implementation of a data model's organization of data within a physical memory. As such, a data structure is formed of specific electrical or magnetic structural elements in a memory. A data structure imposes physical organization on the data stored in the memory as used by an application program executed using a processor.

Data processing system 1700 may include one or more Input/Output (I/O) interfaces 1718 communicatively linked to bus 1706. I/O interface(s) 1718 allow data processing system 1700 to communicate with one or more external devices and/or communicate over one or more networks such as a local area network (LAN), a wide area network (WAN), and/or a public network (e.g., the Internet). Examples of I/O interfaces 1718 may include, but are not limited to, network cards, modems, network adapters, hardware controllers, etc. Examples of external devices also may include devices that allow a user to interact with data processing system 1700 (e.g., a display, a keyboard, and/or a pointing device) and/or other devices such as accelerator card.

Data processing system 1700 is only one example implementation. Data processing system 1700 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

As used herein, the term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. Cloud computing promotes availability and may be characterized by on-demand self-service, broad network access, resource pooling, rapid elasticity, and measured service.

The example of FIG. 17 is not intended to suggest any limitation as to the scope of use or functionality of example implementations described herein. Data processing system 1700 is an example of computer hardware that is capable of performing the various operations described within this disclosure. In this regard, data processing system 1700 may include fewer components than shown or additional components not illustrated in FIG. 17 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular embodiments only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user” refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the terms “one embodiment,” “an embodiment,” “in one or more embodiments,” “in particular embodiments,” or similar language mean that a particular feature, structure, or characteristic described in connection with the embodiment is included in at least one embodiment described within this disclosure. Thus, appearances of the aforementioned phrases and/or similar language throughout this disclosure may, but do not necessarily, all refer to the same embodiment.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the inventive arrangements described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the inventive arrangements described herein.

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various embodiments of the disclosed technology have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method, comprising:
detecting, by computer hardware, a carry chain instance of a circuit design that is under-utilized, wherein the carry chain instance has a first number of logic levels and includes one or more carry chain primitives dedicated for implementing carry chain logic;
generating, by the computer hardware, an updated carry chain instance having a second number of logic levels less than the first number of logic levels; and
replacing, by the computer hardware and within the circuit design, the carry chain instance with the updated carry chain instance.

2. The method of claim 1, wherein the generating the updated carry chain instance comprises:
replacing an entirety of the carry chain instance with one or more general-purpose lookup-table primitives as the updated carry chain instance.

3. The method of claim 1, wherein the generating the updated carry chain instance comprises:
replacing a portion of the carry chain instance with one or more general-purpose lookup-table primitives resulting in the updated carry chain instance.

4. The method of claim 1, wherein the generating the updated carry chain instance comprises:
detecting a selected circuit component that drives the carry chain instance and one or more other loads;
creating a replicated version of the selected circuit component to drive the one or more other loads; and
absorbing the selected circuit component into the carry chain instance resulting in the updated carry chain instance.

5. The method of claim 1, wherein the generating the updated carry chain instance comprises:
detecting a selected circuit component of an input cone of the carry chain instance that is decomposable;
decomposing the selected circuit component of the input cone into a first portion and a second portion; and
absorbing the first portion into a circuit component preceding the selected circuit component and the second portion into the carry chain instance resulting in the updated carry chain instance.

6. The method of claim 1, wherein the generating the updated carry chain instance comprises:
detecting a selected component of an output cone of the carry chain instance; and
absorbing the selected component into the carry chain instance resulting in the updated carry chain instance.

7. The method of claim 1, further comprising:
detecting that the carry chain instance is under-utilized by detecting that a heuristic comprising a ratio of a number of input pins of the one or more carry chain primitives of the carry chain instance connected to an active signal to a total number of input pins of the one or more carry chain primitives exceeds a predetermined threshold.

8. The method of claim 1, further comprising:
detecting that the carry chain instance is under-utilized by detecting that a number of input signals cut by an input cut for the carry chain instance is less than or equal to an input signal threshold and a number of output signals cut by an output cut of the carry chain instance is less than or equal to an output signal threshold.

9. The method of claim 1, further comprising:
selecting a carry chain optimization technique from a plurality of carry chain optimization techniques based on one or more heuristics.

10. A system, comprising:
a memory capable of storing program instructions; and
a hardware processor capable of executing the program instructions to perform operations including:
detecting a carry chain instance of a circuit design that is under-utilized, wherein the carry chain instance has a first number of logic levels and includes one or more carry chain primitives dedicated for implementing carry chain logic;
generating an updated carry chain instance having a second number of logic levels less than the first number of logic levels; and
replacing, within the circuit design, the carry chain instance with the updated carry chain instance.

11. The system of claim 10, wherein the generating the updated carry chain instance comprises:
replacing an entirety of the carry chain instance with one or more general-purpose lookup-table primitives as the updated carry chain instance.

12. The system of claim 10, wherein the generating the updated carry chain instance comprises:
replacing a portion of the carry chain instance with one or more general-purpose lookup-table primitives resulting in the updated carry chain instance.

13. The system of claim 10, wherein the generating the updated carry chain instance comprises:
detecting a selected circuit component that drives the carry chain instance and one or more other loads;
creating a replicated version of the selected circuit component to drive the one or more other loads; and
absorbing the selected circuit component into the carry chain instance resulting in the updated carry chain instance.

14. The system of claim 10, wherein the generating the updated carry chain instance comprises:
detecting a selected circuit component of an input cone of the carry chain instance that is decomposable;
decomposing the selected circuit component of the input cone into a first portion and a second portion; and
absorbing the first portion into a circuit component preceding the selected circuit component and the second portion into the carry chain instance resulting in the updated carry chain instance.

15. The system of claim 10, wherein the generating the updated carry chain instance comprises:
detecting a selected component of an output cone of the carry chain instance; and
absorbing the selected component into the carry chain instance resulting in the updated carry chain instance.

16. The system of claim 10, wherein the hardware processor is capable of executing the program instructions to perform operations including:
detecting that the carry chain instance is under-utilized by detecting that a heuristic comprising a ratio of a number of input pins of the one or more carry chain primitives of the carry chain instance connected to an active signal to a total number of input pins of the one or more carry chain primitives exceeds a predetermined threshold.

17. The system of claim 10, wherein the hardware processor is capable of executing the program instructions to perform operations including:
detecting that the carry chain instance is under-utilized by detecting that a number of input signals cut by an input cut for the carry chain instance is less than or equal to an input signal threshold and a number of output signals cut by an output cut of the carry chain instance is less than or equal to an output signal threshold.

18. The system of claim 10, further comprising:
selecting a carry chain optimization technique from a plurality of carry chain optimization techniques based on one or more heuristics.

19. A computer program product comprising a computer readable storage medium having program instructions embodied therewith, wherein the program instructions are executable by computer hardware to cause the computer hardware to initiate executable operations comprising:
detecting a carry chain instance of a circuit design that is under-utilized, wherein the carry chain instance has a first number of logic levels and includes one or more carry chain primitives dedicated for implementing carry chain logic;
generating an updated carry chain instance having a second number of logic levels less than the first number of logic levels; and
replacing, within the circuit design, the carry chain instance with the updated carry chain instance.

20. The computer program product of claim 19, wherein the program instructions are executable by the computer hardware to initiate operations further comprising:
replacing the carry chain instance in whole or in part with one or more general-purpose lookup-table primitives as the updated carry chain instance.
